(19) United States
(12) Patent Application Publication
(10) Pub. No.: US 2011/0174981 A1
(43) Pub. Date: Jul. 21, 2011

(54) Photodiode Array, Radiation Detector and Method for Producing Such a Photodiode Array And Such A Radiation Detector

(75) Inventors: Michael Miess, Baiersdorf (DE); Stefan Wirth, Erlangen (DE)

(73) Assignee: SIEMENS AKTIENGESELLSCHAFT, Munich (DE)

(21) Appl. No.: 13/006,519

(22) Filed: Jan. 14, 2011

(30) Foreign Application Priority Data
Jan. 18, 2010 (DE) 10 2010 004 890.9

(51) Int. Cl. G01T 1/20; G01T 1/24; H01L 31/18

(52) U.S. Cl. 250/370.11; 438/69; 257/E31.126

(57) ABSTRACT

A photodiode array for a radiation detector is disclosed, including a multiplicity of photodiodes arranged in a structured fashion, the photodiodes respectively having an active pixel region for converting light into electrical signals. In at least one embodiment, a transparent oxide layer with a refractive index comparable to the photodiodes is arranged on the active pixel region of at least some of the photodiodes on a side of the photodiode array provided for arranging a scintillator array. Compared to known photodiode arrays, the oxide layer replaces an adhesive. As a result of equalizing the refractive indices, light incident on the interface between the oxide layer and the photodiode array is refracted or reflected to a lesser extent. This reduces the optical crosstalk between adjacent pixels. Moreover, the active pixel regions of the photodiodes become optically visible as a result of the oxide layer. This therefore provides conditions for precisely aligning the photodiode array relative to the scintillator array by way of optical monitoring. Overall, compared to known radiation detectors, this procedure can increase the effective light yield. At least one embodiment of the invention moreover relates to a corresponding method for producing such a photodiode array and such a radiation detector.

### PRIORITY STATEMENT

The present application hereby claims priority under 35 U.S.C. §119 on German patent application number DE 10 2010 004 890.9 filed Jan. 18, 2010, the entire contents of which are hereby incorporated herein by reference.

### FIELD

At least one embodiment of the invention generally relates to a photodiode array and a radiation detector. At least one embodiment of the invention moreover relates to a corresponding method for producing such a photodiode array and such a radiation detector.

### BACKGROUND

A radiation detector for imaging medical equipment, for example for a computed tomography, PET or SPECT scanner, is used for converting radiation, e.g. X-ray or gamma radiation, into visible light. Until now, use has usually been made of indirect-conversion radiation detectors in the aforementioned modalities. Such indirect-conversion radiation detectors convert the radiation into electrical signals in two stages. In a first stage, the beams are converted into optically visible light pulses by way of a scintillator array. The scintillator array has a pixel-like structure for obtaining a certain spatial resolution. The generated light pulses are subsequently converted into electrical signals in a second stage by way of a photodiode array that is optically coupled to the scintillator array. The photodiode array has a multiplicity of individual photodiodes, which are arranged in a structured fashion in accordance with the scintillator array. The spatially-resolved electrical signals generated thereby are the starting point for reconstructing an image of an examined object or an examined patient.

As a result of production processes, the known radiation detectors are connected with the following disadvantages: when a radiation detector is produced, the scintillator array is bonded to the surface of the photodiode array using an optical adhesive. In the process, the scintillator array is first of all aligned with respect to the photodiode array and prefixed at a certain distance from the surface of the photodiode array. The remaining interspaces are subsequently filled by an optical underfill adhesive. The scintillators and the photodiodes are made of materials with comparable refractive indices in the region of between 3 and 4. However, compared to this, the adhesive has a substantially lower refractive index. As a result of these different refractive indices, light pulses emerging on the underside of the scintillator are significantly refracted and partially reflected on the planar optical transitions between the scintillator and the adhesive, and also between the adhesive and the photodiode. This is because in principle reflection and refraction increase with the differences in the refractive indices between the individual layers. However, further equalization of the refractive indices by way of an appropriate selection of an adhesive substance is not possible as a result of the required optical transparency in the active pixel regions for a transport of light between the photodiode and the scintillator.

Reflection and refraction of the light on the layer interfaces leads to portions of light being transferred within the adhesive layer to adjacent pixels. This optical crosstalk falsifies the electrical signals used for image reconstruction, which in turn is connected with deterioration in the image quality that can be obtained. Moreover, the multiple reflections, connected with refraction and reflection, are afflicted with losses in the light power. Hence, optical crosstalk and multiple reflections overall lead to a reduction in the effective light yield of the radiation detector.

Moreover, erroneous positioning of the scintillator array with respect to the photodiode array may lead to part of the light emerging from the respective scintillator not being entirely incident on the active pixel region of the corresponding photodiode and thus being lost to the signal generation. There is a risk of erroneous positioning particularly in the case of photodiode arrays illuminated from the rear because the active pixel regions identified by doping are not visible on the rear side provided for attaching the scintillator array. That is to say the scintillator array is alternatively aligned in this case with reference to the outer edges of the photodiode array, taking into account previous knowledge of the position of the photodiodes in relation to the outer edges. In general, there is imprecision relating to the positions of the photodiodes with respect to the outer edge due to production tolerances during the cutting process and possible edge breakouts during cutting. These circumstances also lead to a reduction in the effective light yield of the radiation detector.

### SUMMARY

In embodiments of the present invention, a photodiode array, a radiation detector and a method are disclosed for producing such a photodiode array and such a radiation detector such that the conditions are provided for improved light coupling between the scintillators and photodiodes for increasing an effective light yield.

In at least one embodiment, a photodiode array is disclosed. In at least one embodiment, a radiation detector is disclosed. In at least one embodiment, a production method for such a photodiode array and such a radiation detector is disclosed. Advantageous embodiments and developments are the subject matter of dependent claims.

The photodiode array according to at least one embodiment of the invention for a radiation detector comprises a multiplicity of photodiodes arranged in a structured fashion, the latter respectively having an active pixel region for converting light into electrical signals, wherein a transparent oxide layer with a refractive index comparable to the photodiodes is arranged on the active pixel region of at least some of the photodiodes on a side of the photodiode array provided for arranging a scintillator array.

The oxide layer arranged on the photodiode array on the active pixel regions serves as optical coupling element between the photodiodes and the scintillators to be affixed for assembling a radiation detector. Here, in the region of the active pixel region, the oxide layer replaces the adhesive used in previous radiation detectors. There is substantially less refraction and reflection of the light at the interfaces between the oxide layer and the photodiodes as a result of the produced comparable refractive indices thereof. This reduces light transfer within the oxide layer and thus optical crosstalk in adjacent pixels. Moreover, there is a reduction in the number of multiple reflections prior to the light coupling into the photodiode and in the loss of light power connected therewith. Thus, overall, these measures provide the conditions for improved light coupling between scintillators and photodiodes for increasing an effective light yield.

As a result of the optically different material properties of the scintillators and the introduced septa for structural separation thereof, the structure of the scintillators in a scintillator array can in principle be recognized very easily, even in the previous radiation detectors. The inventors have recognized that the visibility of this structure can be used in the assembly of a radiation detector in order to improve the relative positioning between the photodiode array and the scintillator array. By making the structure or the array-shaped pattern of the photodiodes directly visible as a result of the selective application of the oxide layer in the region of the active pixel surfaces on the light-entry side of the photodiode array, it is possible to align the scintillator array precisely with respect to the photodiode array by way of optical monitoring. Here it is merely necessary to align the two visible structures when aligning the arrays relative to one another. Such an alignment by way of optical monitoring can be carried out with very high precision. Moreover, the oxide layer can be generated on the surface of the photodiode array with very high precision in the region of approximately 5 μm. The systematic error in the positioning of the components on the basis of the optically visible structure as a reference is substantially smaller than positioning on the basis of an outer edge of the array as a result of the high tolerance levels that can be generated during the cutting process or as a result of edge breakouts.

The visibility of the pixel structure on the photodiode array is advantageous, particularly when assembling a backlit radiation detector, because the pixel structure on the radiation-entry side of the photodiode array in such a radiation detector would not be visible without the oxide layer arranged on the active pixel surfaces.

Applying the oxide layer thus provides the conditions for an exact alignment of the two arrays to one another, which in turn leads to an increase in the light yield that can be obtained.

Very comparable refractive indices between the photodiode array and the oxide layer can advantageously be obtained if the oxide layer is a silicon oxide layer.

The oxide layer preferably has a layer thickness of at least 5 μm, preferably 20 μm. Thus it additionally satisfies the function of a spacer for compensating for production-related unevenness on the surface of the photodiode array or on the scintillator array to be applied. Additional spacers, as utilized in conventional radiation detectors for compensating for this unevenness, are therefore no longer required. This simplifies the production process for assembling a radiation detector.

According to a second aspect of at least one embodiment of the invention, the radiation detector according to the invention additionally has a scintillator array arranged directly on the oxide layer of the photodiode array, which scintillator array comprises a multiplicity of scintillators arranged in a structured fashion in accordance with the photodiode array, wherein the oxide layer has a refractive index comparable to the scintillators. Hence the photodiode array, the scintillator array and the oxide layer arranged therebetween as optical coupling element have comparable refractive indices. The light that is incident on the interfaces is therefore hardly refracted or reflected. As mentioned previously, the portion of light transferred in the oxide layer to adjacent pixels is therefore substantially lower than in the known radiation detectors.

In order to produce a mechanical connection between the photodiode array and the scintillator array, the interspaces between adjacent active pixel regions are advantageously filled by an adhesive in the oxide layer. Put differently, the channels formed by the structure of the oxide layer are flooded with the adhesive, starting from one side, after affixing the scintillator array.

Hence, in the region of the active pixel surfaces, there is no longer a need for an adhesive for attaching the scintillator array. This therefore dispenses with the requirement of the adhesive to be optically transparent. This therefore increases the number of adhesives that may, in principle, be used. The selection can be brought about under the aspect of improved adhesion, processability and/or reduced costs.

In an advantageous embodiment of the invention, the oxide layer is arranged on all of the active pixel regions and the adhesive for filling the interspaces is explicitly optically opaque. This completely avoids transfer of light within the layer and hence optical crosstalk to adjacent pixels.

The method according to at least one embodiment of the invention for producing a photodiode array for a radiation detector comprises the following method steps:

a) A multiplicity of photodiodes arranged in a structured fashion are formed at first, wherein each of the photodiodes comprises an active pixel region for converting light into electrical signals.
b) A transparent oxide layer with a refractive index comparable to the photodiodes is subsequently applied to the active pixel region of at least some of the photodiodes on a side of the photodiode array provided for arranging a scintillator array.

A known PVD method can be used to evaporate the oxide layer onto the surface of the photodiode array in a particularly precise fashion and with simple devices.

A further aspect of at least one embodiment of the invention relates to the production of a radiation detector and to the use of such a photodiode array, wherein the following method steps are carried out subsequent to the production of the photodiode array:
a) A scintillator array with a multiplicity of scintillators, arranged in a structured fashion in accordance with the photodiode array, is arranged on the oxide layer, wherein the oxide layer has a refractive index comparable to the scintillators.
b) Interspaces between the adjacent active pixel regions are filled by an adhesive in the oxide layer.

The adhesive layer in known radiation detectors typically has a thickness of up to 100 μm. The radiation detector according to at least one embodiment of the invention has layer thicknesses in the region of between 5 and 20 μm. Thus, the use of an oxide layer allows a substantial reduction in the distance between the photodiode array and the scintillator array. Since the risk of light transfer and hence the risk of optical crosstalk is greater in thick layers than in thin layers, the effective light yield is increased in the radiation detector according to the invention compared to the known radiation detectors.

### BRIEF DESCRIPTION OF THE DRAWINGS

In the following text, the invention will be explained in more detail on the basis of exemplary embodiments and on the basis of drawings, in which:

FIG. 1 shows a schematic illustration of a computed tomography scanner with a radiation detector according to an embodiment of the invention,

FIG. 2 shows a perspective view of a photodiode array according to an embodiment of the invention, and

FIG. 3 shows a side view of a radiation detector according to an embodiment of the invention.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

Parts with the same effect have been provided with the same reference sign in the figures. In the case of elements that are repeated within one figure, e.g. the illustrated pixel 9, only one element has in each case been provided with a reference sign for reasons of clarity. The illustrations in the figures are schematic and not necessarily true to scale, with the scales being able to vary between the figures.

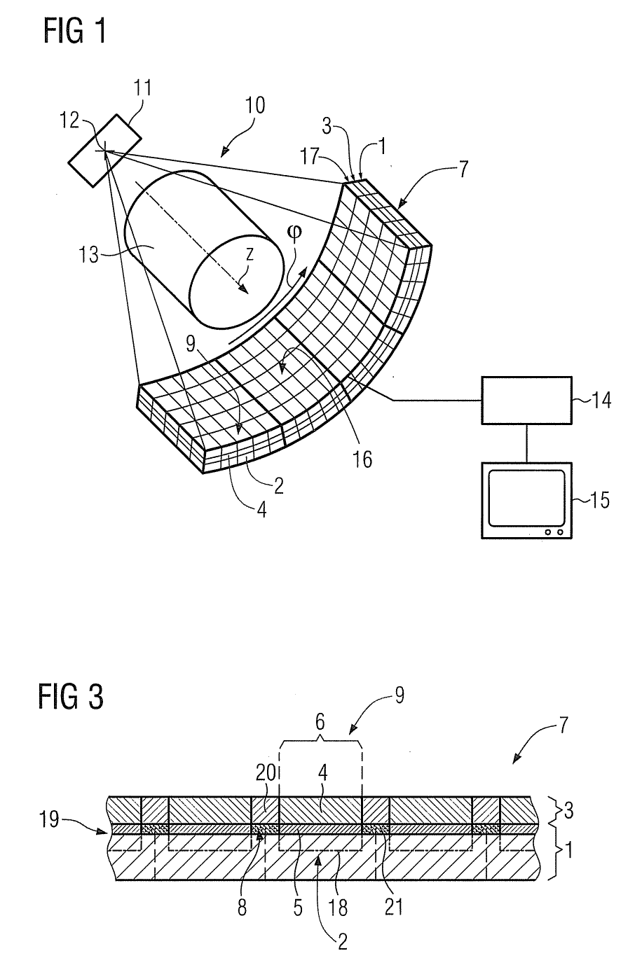

FIG. 1 shows a computed tomography scanner 10, which comprises a radiation source 11 in the form of an X-ray tube with an X-ray beam fan emerging from the focus 12 thereof. The X-ray beam fan penetrates an object 13 to be examined or a patient and is incident on a radiation detector 7, in this case an X-ray detector.

The X-ray tube 11 and the X-ray detector 7 are arranged mutually opposing one another on a gantry (not illustrated here) of the computed tomography scanner 10, which gantry can be rotated in a φ-direction about a system axis Z (=patient axis) of the computed tomography scanner 10. The φ-direction thus represents the circumferential direction of the gantry and the Z-direction represents the longitudinal direction of the object 13 to be examined.

When the computed tomography scanner 10 is in operation, the X-ray tube 11 and the X-ray detector 7 arranged on the gantry rotate around the object 13, with X-ray recordings of the object 13 being obtained from different projection directions. For each X-ray projection, X-ray radiation that has passed through the object 13 and has been attenuated thereby is incident on the X-ray detector 7. In the process, the X-ray detector 7 produces electrical signals from the incident X-ray quanta, which electrical signals correspond to the intensity of the incident X-ray radiation. An evaluation unit 14 subsequently uses the signals registered by the X-ray detector 7 to calculate one or more two-dimensional or three-dimensional images of the object 13 in a known fashion, and these images can be displayed on a display unit 15.

In the present example, the X-ray detector 7 is assembled overall from four individual radiation detector modules 16 or X-ray detector modules, which are arranged next to one another in the φ-direction. Reference is made to the fact that the segmentation into X-ray detector modules 16 is merely selected for reasons of a simpler design of an X-ray detector 7 with an arc-shaped embodiment and for reasons of simpler production and maintenance. The function and design of an integrally produced X-ray detector do not differ from a modularly produced X-ray detector 7.

The primary radiation emanating from the focus 12 of the X-ray tube 11 is, inter alia, scattered in different spatial directions in the object 13. This so-called secondary radiation generates signals in the pixels 9 or detector elements that cannot be distinguished from the primary-radiation signals required for the image reconstruction. In order to limit the influence of the secondary radiation, a collimator arrangement 17 substantially only allows the portion of the X-ray radiation emanating from the focus 12, i.e. the primary radiation portion, to pass onto the X-ray detector 7 in an unimpeded fashion, while the secondary radiation is ideally absorbed in its entirety.

For the spatially-resolved conversion of the incident X-ray quanta into light, the X-ray detector 7 has a scintillator array 3 and it also has a photodiode array 1 for converting the light into electrical signals, with an oxide layer 5 being arranged between the two arrays 3, 1 in the region of the active pixel regions 6. The photodiode array 1 and the X-ray detector 7 are explained in more detail on the basis of the following figures:

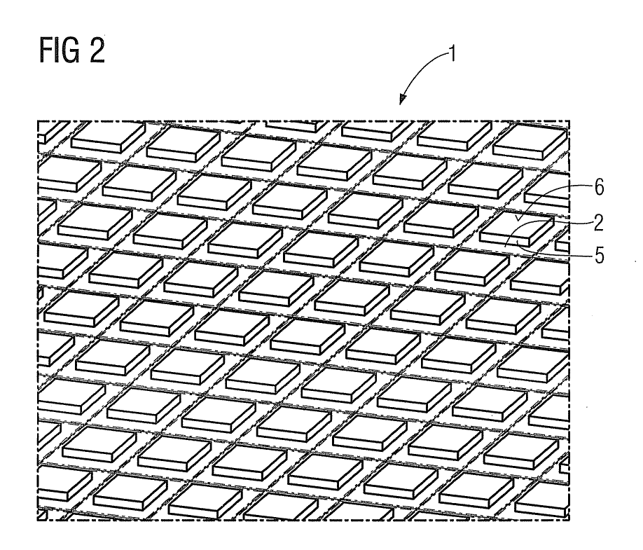

FIG. 2 shows a photodiode array 1 according to the invention. It comprises a multiplicity of photodiodes 2, arranged to form a matrix-shaped array, which are produced on the basis of a silicon wafer in this example embodiment. During the production process, the silicon wafer passes through a plurality of chemical baths in advance in order to repair cutting damage and to form a surface suitable for catching light. A p-n junction is subsequently formed for each photodiode 2. The silicon wafer is usually provided with p-type basic doping, for example by boron atoms introduced into the crystal structure. An n-doping 18 of the silicon wafer is brought about by way of diffusion of e.g. phosphorous atoms into the upper layer of the silicon wafer, said layer having a thickness of approximately 1 μm. The n-doping is in each case undertaken in a selective fashion by appropriate masking in the region of the active pixel region 6 to be formed in the respective photodiode 2. The layer is passivated after the doping procedure by applying a thin protective layer. Light incident on this active pixel region 6 is converted into an electrical signal by interaction processes between the incident light quanta and the electrons present in the p-n junction. The doping procedure has made the active pixel regions 6 optically visible. In a subsequent production step, an oxide layer 5, with a refractive index comparable to the photodiodes 2, is respectively selectively applied to the active pixel regions 6 formed in this fashion. Hence silicon, for example, is used as basis material for building up the oxide layer 5 in this exemplary embodiment. The oxide layer 5 is built up step-by-step up to a thickness of between 5 and 20 μm by evaporation of the crystals. Evaporation can be carried out at low temperatures of less than 100 degrees, and so the completely processed photodiodes 2 are not damaged during the build-up of the oxide layer 5.

Such a photodiode array 1 is used to assemble a radiation detector 7 according to the invention, shown in a side view in FIG. 3. Here the scintillator array 3 is arranged directly on the oxide layer 5. The scintillator array has a refractive index comparable to the oxide layer 5. Hence, materials such as Gd₂O₂S:Pr or CsI:Tl, doped with activators, are possible scintillator materials. The individual scintillators 3 are mutually separated by so-called septa 20 in accordance with the structure of the photodiode array 1 and are thus optically visible. When the scintillator array 3 is arranged on the photodiode array 1, the surfaces of the active pixel regions 6 of the photodiodes 2, identified by the oxide layer 5, are aligned with light-emergence surfaces of the scintillators 4, and so the septa 20 come to rest in the interspaces between the oxide layers 5 of adjacent pixels 9. The interspaces form channels, into which the adhesive 8 is introduced from the side in order to fix the two arrays 3, 1 in a mechanical fashion. The thickness of the oxide layer 5 should be selected such that, on the one hand, unevenness on the surfaces of the photodiode and scintillator arrays 3, 1 is compensated for. On the other hand, the adhesive 8 must be able to be introduced into the channels because of the viscosity of the former. Therefore, the layer thickness should be selected as a function of the viscosity of the adhesive and as a function of the expected unevenness of the surfaces of the scintillator array 3 or the photodiode array 1. The adhesive 8 is selected to be optically opaque, and so optical crosstalk between adjacent pixels is prevented. In this exemplary embodiment, the adhesive has particles 21 that reflect the light transferred in the oxide layer 5. By way of example, metal particles can be used as particles 21 for this purpose.

In summary, the following statement may be made:

An embodiment of the invention relates to a photodiode array 1 for a radiation detector 7 with a multiplicity of photodiodes 2 arranged in a structured fashion, the latter respectively having an active pixel region 6 for converting light into electrical signals, wherein a transparent oxide layer 5 with a refractive index comparable to the photodiodes 2 is arranged on the active pixel region 6 of at least some of the photodiodes 2 on a side of the photodiode array 1 provided for arranging a scintillator array 3. Compared to known photodiode arrays, the oxide layer 5 replaces an adhesive. As a result of equalizing the refractive indices, light incident on the interface between the oxide layer 5 and the photodiode array 1 is refracted or reflected to a lesser extent. This reduces the optical crosstalk between adjacent pixels 9. Moreover, the active pixel regions 6 of the photodiodes 2 become optically visible as a result of the oxide layer 5. This therefore provides conditions for precisely aligning the photodiode array 1 relative to the scintillator array 3 by way of optical monitoring. Overall, compared to known radiation detectors, this procedure can increase the effective light yield. At least one embodiment of the invention moreover relates to a corresponding method for producing such a photodiode array 1 and such a radiation detector 7.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combinable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Still further, any one of the above-described and other example features of the present invention may be embodied in the form of an apparatus, method, system, computer program, non-transitory computer readable medium and non-transitory computer program product. For example, of the aforementioned methods may be embodied in the form of a system or device, including, but not limited to, any of the structure for performing the methodology illustrated in the drawings.

Even further, any of the aforementioned methods may be embodied in the form of a program. The program may be stored on a non-transitory computer readable medium and is adapted to perform any one of the aforementioned methods when run on a computer device (a device including a processor). Thus, the non-transitory storage medium or non-transitory computer readable medium, is adapted to store information and is adapted to interact with a data processing facility or computer device to execute the program of any of the above mentioned embodiments and/or to perform the method of any of the above mentioned embodiments.

The non-transitory computer readable medium or non-transitory storage medium may be a built-in medium installed inside a computer device main body or a removable non-transitory medium arranged so that it can be separated from the computer device main body. Examples of the built-in non-transitory medium include, but are not limited to, rewriteable non-volatile memories, such as ROMs and flash memories, and hard disks. Examples of the removable non-transitory medium include, but are not limited to, optical storage media such as CD-ROMs and DVDs; magneto-optical storage media, such as MOs; magnetism storage media, including but not limited to floppy disks (trademark), cassette tapes, and removable hard disks; media with a built-in rewriteable non-volatile memory, including but not limited to memory cards; and media with a built-in ROM, including but not limited to ROM cassettes; etc. Furthermore, various information regarding stored images, for example, property information, may be stored in any other form, or it may be provided in other ways.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A photodiode array for a radiation detector, comprising:
a multiplicity of photodiodes arranged in a structured fashion, the multiplicity of photodiodes each respectively including an active pixel region for converting light into electrical signals, wherein a transparent oxide layer with a refractive index comparable to the photodiodes is arranged on the active pixel region of at least some of the multiplicity of photodiodes on a side of the photodiode array provided for arranging a scintillator array.

2. The photodiode array as claimed in claim 1, wherein the oxide layer is a silicon oxide layer.

3. The photodiode array as claimed in claim 1, wherein the oxide layer includes a layer thickness of at least 5 μm.

4. The photodiode array as claimed in claim 1, wherein the oxide layer includes a layer thickness of at least 20 μm.

5. A radiation detector, comprising:
the photodiode array as claimed in claim 1; and
a scintillator array including, arranged thereon, a multiplicity of scintillators arranged in a structured fashion in accordance with the photodiode array, wherein the scintillator array is arranged directly on the oxide layer and wherein the oxide layer includes a refractive index comparable to the scintillators.

6. The radiation detector as claimed in claim 5, wherein interspaces between adjacent active pixel regions are filled by an adhesive in the oxide layer.

7. The radiation detector as claimed in claim 5, wherein the oxide layer is arranged on all of the active pixel regions and the adhesive for filling the interspaces is optically opaque.

8. A method for producing a photodiode array for a radiation detector, comprising:
forming a multiplicity of photodiodes arranged in a structured fashion, wherein each of the multiplicity of photodiodes includes an active pixel region for converting light into electrical signals; and
applying a transparent oxide layer, with a refractive index comparable to the multiplicity of photodiodes, to the active pixel region of at least some of the multiplicity of photodiodes on a side of the photodiode array provided for arranging a scintillator array.

9. The method for producing a photodiode array as claimed in claim 8, wherein the oxide layer is evaporated thereon.

10. The method for producing a photodiode array as claimed in claim 8, wherein the oxide layer is applied until the layer has a thickness of at least 5 μm.

11. The method for producing a photodiode array as claimed in claim 8, wherein the oxide layer is applied until the layer has a thickness of at least 20 μm.

12. A method for producing a radiation detector, comprising:
producing a photodiode array as claimed in claim 8;
arranging a scintillator array with a multiplicity of scintillators, arranged in a structured fashion in accordance with the photodiode array, on the oxide layer, wherein the oxide layer includes a refractive index comparable to the scintillators; and
filling interspaces between the adjacent active pixel regions by an adhesive in the oxide layer.

13. The method for producing a radiation detector as claimed in claim 12, wherein use is made of an optically opaque adhesive.

14. The photodiode array as claimed in claim 2, wherein the oxide layer includes a layer thickness of at least 5 μm.

15. The photodiode array as claimed in claim 2, wherein the oxide layer includes a layer thickness of at least 20 μm.

16. A radiation detector, comprising:
the photodiode array as claimed in claim 2; and
a scintillator array including, arranged thereon, a multiplicity of scintillators arranged in a structured fashion in accordance with the photodiode array, wherein the scintillator array is arranged directly on the oxide layer and wherein the oxide layer includes a refractive index comparable to the scintillators.

17. The radiation detector as claimed in claim 6, wherein the oxide layer is arranged on all of the active pixel regions and the adhesive for filling the interspaces is optically opaque.

18. The method for producing a photodiode array as claimed in claim 9, wherein the oxide layer is applied until the layer has a thickness of at least 5 μm.

19. The method for producing a photodiode array as claimed in claim 9, wherein the oxide layer is applied until the layer has a thickness of at least 20 μm.
